(19) United States
(12) Patent Application Publication
(10) Pub. No.: US 2015/0132931 A1
(43) Pub. Date: May 14, 2015

(54) HIGH-THROUGHPUT THERMAL PROCESSING METHODS FOR PRODUCING HIGH-EFFICIENCY CRYSTALLINE SILICON SOLAR CELLS

(71) Applicant: Solexel, Inc., Milpitas, CA (US)

(72) Inventors: Pawan Kapur, Burlingame, CA (US); Mehrdad M. Moslehi, Los Altos, CA (US); Sean M. Seutter, San Jose, CA (US); Mohammed Islam, Mountain House, CA (US); Anand Deshpande, Cupertino, CA (US)

(21) Appl. No.: 14/321,802

(22) Filed: Jul. 1, 2014

Related U.S. Application Data
(60) Provisional application No. 61/841,501, filed on Jul. 1, 2013.

(51) Int. Cl. H01L 31/18

(52) U.S. Cl. CPC H01L 31/1864; H01L 31/1804; H01L 31/1876
USPC 438/558; 438/57

(57) ABSTRACT

A method for thermal processing of a silicon substrate wherein first a silicon substrate is heated to an idle load temperature in the range of approximately 700° to 900° C. The silicon substrate is then heated to a temperature in the range of approximately 975° to 1200° C. in less than approximately 20 minutes. After thermal processing, the silicon substrate is cooled to an idle unload temperature in the range of approximately 700° to 900° C. in less than approximately 20 minutes.

### CROSS-REFERENCE TO RELATED APPLICATIONS

This application claims the benefit of U.S. provisional patent application 61/841,501 filed on Jul. 1, 2013 which is hereby incorporated by reference in its entirety.

### FIELD OF THE INVENTION

The present disclosure relates in general to the field of silicon processing, and more particularly to silicon thermal processing.

### BACKGROUND

For high efficiency crystalline silicon solar cells produced on crystalline silicon substrates, such as monocrystalline Czochralski (CZ) material, it is imperative to mitigate minority-carrier lifetime (MCL) degradation and substantially maintain the starting bulk wafer MCL during and throughout solar cell processing, including through any high temperature processing steps. Czochralski (CZ) monocrystalline silicon starting wafers used to manufacture crystalline silicon solar cells are particularly susceptible to high temperature solar cell processing (for instance, thermal processing in the range of about 900° C. and 1200° C., and more specifically in the range of about 950° C. to 1100° C.), due to various effects including but not limited to the interstitial oxygen impurities and their subsequent precipitation in CZ silicon (resulting in reduction of MCL and processed solar cell efficiency). High-temperature processes utilized in crystalline silicon solar cell manufacturing are typically in the range of 950° C. to 1100° C. and are used to drive dopants, perform thermal anneal, or form passivation through oxidation (or oxynitridation). Chochralski (CZ) grown single-crystal silicon wafers are known to have higher levels of interstitial oxygen as compared to float-zone (FZ) or epitaxially grown single crystalline silicon wafers (or substrates). One of the deleterious consequences of higher oxygen content in CZ silicon wafers is precipitation of oxygen atoms in the crystal to form defects (in the form of SiOx or silicon oxide precipitates) during solar cell wafer processing at higher temperatures (and/or during thermal processing involving a combination of extended lower or medium temperature thermal processing, for instance, in the range of 600° C. and 900° C., and higher temperature thermal processing, for instance in the range of 900° C. and 1200° C.). This, in turn, increases recombination of the minority carriers and decreases minority carrier lifetime (MCL) in the bulk and ultimately compromises solar cell efficiency.

Often, high-temperature thermal processing used for manufacturing high-efficiency crystalline silicon solar cells is performed in resistively-heated batch tube furnaces, comprising quartz tubes and quartz boats holding a plurality of wafers. In processing operation, these furnaces often rest between high temperature thermal processing at temperatures (i.e. idle temperature). The furnace idle temperature during loading and unloading of the quartz boats may be as low as room temperature. The specific idle temperature, along with the ramp rates, not only dictates the throughput of the process, but also has an effect on the electrical properties such as minority carrier lifetime of the wafer.

### BRIEF SUMMARY OF THE INVENTION

Therefore, a need has arisen for silicon thermal processing methods that mitigate or suppress oxygen precipitation and provide high fabrication throughput capabilities. In accordance with the disclosed subject matter, methods are provided which substantially eliminate or reduce disadvantages associated with previously developed silicon thermal processing.

According to one aspect of the disclosed subject matter, a method for thermal processing of a silicon substrate is provided. First a silicon substrate is heated to an idle load temperature in the range of approximately 700° to 900° C. The silicon substrate is then heated to a temperature in the range of approximately 975° to 1200° C. in less than approximately 20 minutes. After thermal processing, the silicon substrate is cooled to an idle unload temperature in the range of approximately 700° to 900° C. in less than approximately 20 minutes.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a high-level representative process flow for processing IBC solar cells from a starting wafer;

FIG. 2 is representative process flow to make minority carrier lifetime test structures;

FIG. 3 is a graph of load/unload temperatures vs measured effective lifetime;

FIG. 4 is a graph of average minority carrier lifetime before a second batch furnace thermal anneal and after a second thermal anneal;

FIG. 5 is a graph of load/unload temperatures vs measured effective lifetime for alternative test structures; and

FIG. 6 is a graphic timeline depiction of the load, thermal processing, and unload process flow.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

The present application provides high-throughput thermal processing methods which suppress or reduce degradation of minority carrier lifetimes of starting silicon substrates (e.g. wafers having a thickness in the range of 10 microns to 160 microns, more specifically, 50 to 150 microns such as CZ wafers, during high temperature processing (for instance, thermal processing in the range of approximately 900° C. and 1200° C., and more specifically in the range of approximately 950° C. to 1100° C.) such as those often used for fabrication of crystalline silicon solar cells. Such high-temperature processing (one or multiple high temperature steps) may be used for applications involving one or a combination of the following: dopant drive-in (for instance, from a deposited dopant source), formation of surface passivation, thermal annealing of existing dielectric passivation to improve passivation properties, annealing out damage, etc. These high temperature processes may last from a few minutes up to multiple hours depending on process specifics.

And although embodiments are detailed in the context of processing back contact/back junction (Interdigitated Back-Contact or IBC) cells which have n-type (e.g., phosphorus doped) starting CZ wafers, the inventive aspects provided herein are equally applicable to other cell architectures with both n and p-type wafers, as well as solar cells produced from other crystalline silicon absorbers such as though formed from epitaxial silicon and other sources such as multi crystalline silicon starting wafers.

The segregation or precipitation of background oxygen atoms commonly present in crystalline silicon wafers (such as interstitial silicon atoms present in CZ silicon) can form defects in single crystal silicon which form undesirable recombination centers for minority carriers—resulting in degradation of minority carrier lifetime and diffusion length. In the context of solar cell processing, the innovative methods in the context of reducing the degradation of the minority carrier lifetime disclosed outline one or a combination of the following aspects: (i) using a relatively high idle batch furnace temperature, set in the temperature range of approximately 700° C. to 900° C. and more specifically in the range of about 750° C. to 850° C. (for instance, at about 800° C.), and, (ii) relatively fast load push and unload pull of the batch wafer boats into and out of the batch furnace tube at the beginning and at the end of the batch thermal furnace process, respectively (for instance, less than approximately ten minutes and more specifically approximately 5 minutes). The idle furnace temperature is the furnace temperature before and after completion of the batch furnace process (or the furnace temperature before loading and after unloading the batch wafer boat). The relatively high idle furnace temperature has several advantages: (i) reduced oxygen precipitation in silicon and minority carrier lifetime degradation, (ii) minimized ramp time from idle temp. to processing temp. and cool down time (for instance, less than approximately twenty minutes and as short as one minute), and (iii) increased batch furnace processing throughput and reduced solar cell processing cost.

The load and unload temperatures disclosed both reduce the thermal budget of high temperature processing—a large thermal budget is a known cause of oxygen precipitation and lifetime reduction in silicon—and increase processing throughput by reducing the ramp cycle as a higher load/unload temperature allows for a faster ramp to the processing temperature. However, certain higher load/unload temperatures may cause thermal shock as the wafer is adjusted from or to room temperature (e.g., the wafer is transported in or out of the furnace). Among other identified effects, increased thermal shock may lead to lifetime degradation and slip dislocations in the wafer. These thermal shock degradations (thermal shock from load/unload temp. to room temp.) may be particularly complex as wafer thickness is decreased. Thus, an optimal load/unload (idle) temperature should provide reduced oxygen precipitation with enhanced gettering action using a limited thermal budget while minimizing thermal shock both before and after processing and providing high processing throughput.

The upper limit of idle temperature may be approximately 900° C. in order to prevent formation of slip dislocations during the fast push and pull of the batch wafer boats. Faster push and/or pull of the batch wafer boats refers to the higher speeds of quartz boat loading at the beginning of the furnace process and the speed of quartz boat unloading at the end of the furnace process as compared to previously known furnace processing (while the furnace tube is at the idle temperature). The idle furnace anneal temperature value may be, for example maintained in the range of about 700° C. to 900° C. and more specifically in the range of about 750° C. to 850° C. (for instance, about 800° C.). The idle furnace temperature range (approximately 700° C. to 900° C. and more specifically in the range of approximately 750° C. to 850° C.) is higher than that of the known furnace processes (e.g., typically approximately 400° C. to 600° C.), while the maximum idle temperature is below the threshold of thermally induced slip dislocations in presence of thermal gradients.

Thus the methods disclosed herein may be used to highly mitigate or suppress deterioration of the bulk minority carrier lifetime in crystalline silicon wafers or absorbers anytime (i.e., from once to multiple times as desired in a particular process) the temperature of the wafer (e.g., CZ wafer) is raised above a threshold high temperature value (e.g., 900° C.) for a certain duration of time (from minutes to hours)—e.g., high temperature processing during the formation of a solar cell for, including but not limited, dopant drive-in, passivation improvement, and/or annealing out damage while mitigating formation of oxygen precipitates.

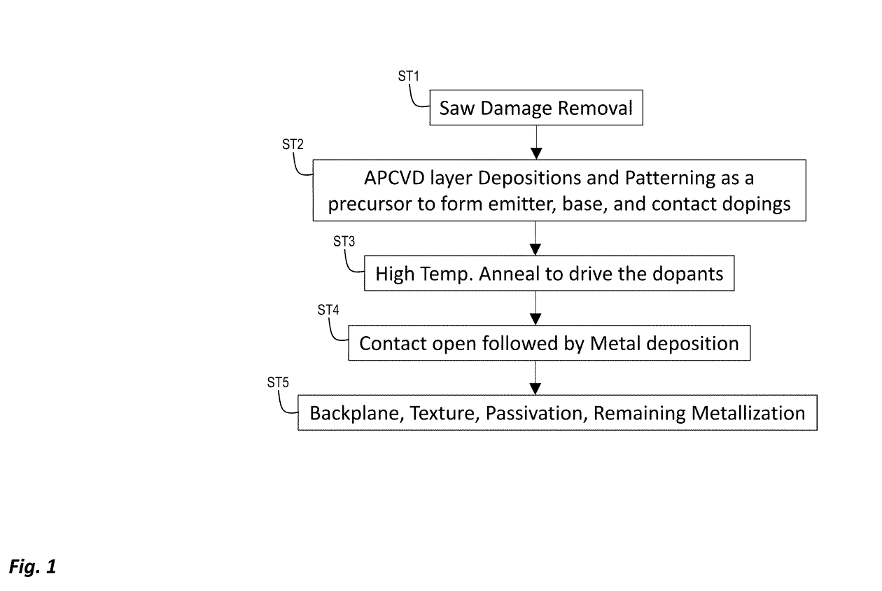

FIG. 1 is a high-level representative process flow for processing IBC solar cells from a starting wafer. ST1 is a wafer saw damage removal process, ST2 is an APCVD layer deposition and patterning process, ST3 is a high temperature furnace process to drive dopants in, anneal, and provide passivation, ST4 is a contact opening and metal deposition process, and ST5 shows subsequent solar cell fabrication processes.

The representative process flow of FIG. 1 is provided as an example and should not be taken in a limiting sense as other solar cell fabrication process flows, including additional IBC process flows, which use at least one high temperature (for instance, thermal processing in the range of approximately 900° C. and 1200° C., and more specifically in the range of approximately 950° C. to 1100° C.) process (typically performed in a batch tube furnace) for anneal, dopant drive, passivation, contact formation, and/or damage removal from previous pre-thermal-processing steps may benefit from the inventive aspects disclosed herein. (e.g., high temp anneal ST3 in FIG. 1).

The process flow of FIG. 1 uses differently doped (both p-type and n-type) Atmospheric-Pressure Chemical-Vapor Deposition (APCVD), or alternatively, Plasma-Enhanced Chemical-Vapor Deposition (PECVD) layers of both boron (or another p-type dopant such as gallium) and phosphorous (or another n-type dopant such as arsenic) doped glass (silicon oxide) to form doped silicon regions (including emitter junction and doped base windows) as well as high-quality passivation on the silicon backside through various process steps. These doped glass layers are subsequently patterned and subjected to thermal processing at higher temperatures to migrate the dopants from the dopant source into the silicon, and form patterned doped n-type and p-type regions on the silicon backside.

The disclosed methods provide for controlling the push/pull of the quartz boats into and out of the batch furnace tube in terms of dwell and load/unload temperature along with ambient (e.g., nitrogen or the combination of an inert gas and an oxidizing ambient) in order to highly mitigate or suppress minority carrier lifetime degradation effect of the furnace process. A fast push pull at an optimal furnace load/unload temperature (idle furnace temperature) of about 800° C. may yield the best minority carrier lifetime and maximize both the open circuit voltage and the resulting conversion efficiency of the solar cells. A push/pull or load/unload temperature (or idle furnace temperature) which is appreciably higher or lower than approximately 800° C. (for example, outside of approximately 750° or 900° C.) may yield worse minority carrier lifetimes depending on a number of factors including cell fabrication processes, cell materials, and resulting cell structure. In the same light, ambient control during push/pull and ramp/cool down steps have shown that use N2 during ramp and cool down is important to maintain the minority carrier lifetime. An idle (load/unload) furnace temperature of about 800° to 850° C. may be optimal in some instances to achieve the best solar cell performance results in conjunction with enhanced furnace process throughput and negligible slip dislocations. However, this optimal idle temperature depends on a number of factors such as the high temperature process itself—for example it depends on the passivation material in case of a high temperature process catered toward getting a high quality passivation.

Lifetime testing structures were used to experimentally determine optimal furnace thermal processing conditions in support of the inventive methods provided herein. The final test structure used to determine the optimum thermal process conditions was a silicon wafer with a symmetric p-n junction and thermal silicon dioxide passivation on both primary surfaces. The test structure yielded effective minority carrier lifetime and was also conducive to extract the leakage current density (Jo) of the emitter. A lower Jo of the emitter (typically expressed in fA/cm2) is desirable as it results in a higher effective lifetime and a higher efficiency through better open circuit voltage.

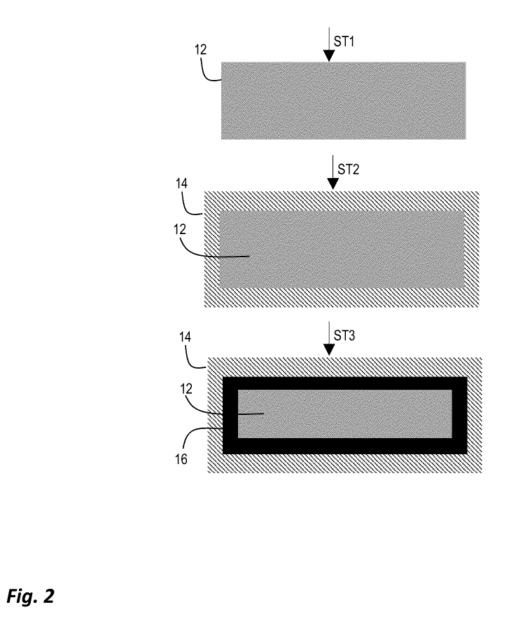

FIG. 2 is representative process flow to make minority carrier lifetime test structures as described above. N-type CZ wafer 12 is shown after saw damage removal in ST1 of FIG. 2 (corresponding to ST1 in FIG. 1). Standard n-type phosphorous doped, mono-crystalline CZ wafers with starting wafer bulk minority carrier lifetime specified at about at least 0.5 ms-1 ms were used as starting wafers. The CZ wafer resistivity was in the range of 1.5 to 5 ohms-cm (Ω.cm) with starting wafer thicknesses on the order of approximately 180 μm. The wafers went through standard Saw Damage Removal (SDR) wet etch followed by an RCA surface clean. Note that after SDR the wafer surface may be rough (surface topography not shown in FIG. 2).

Subsequently, ST2 of FIG. 2 (corresponding to ST2 in FIG. 1) a thin APCVD layer of boron doped silicon oxide (or BSG) 14 was deposited on both sides of wafer 12. The doping in the APCVD is such that in combination with the subsequent anneal temperature, it yields emitter sheet resistance corresponding to a typical IBC cell (e.g. sheet resistance ranges from about 70 to 250 ohms/square depending on the doping concentration of the APCVD layer).

Subsequent to the deposition of the APCVD boron doped glass (or BSG), in ST3 of FIG. 2 (corresponding to ST3 in FIG. 1) the wafers are annealed in a furnace at high temperatures with different thermal processing conditions. This first high temperature anneal for emitter and passivation layer formation shown as boron doped emitter 16. Various load and unload conditions were attempted with high temp. anneal ST3. This anneal is followed by measurements and comparison of measured effective minority carrier lifetimes. The range of parameters are described here to make the test structures represent only an example for testing the methods and are not meant to limit the methods provided herein to the test structures that they were applied to and tested on. Additionally, in some instances a second high temp. anneal (e.g., at temperatures greater than 1000° C.) may further improve lifetime. This second high temp. anneal was performed to observe if wafer lifetime was further improved.

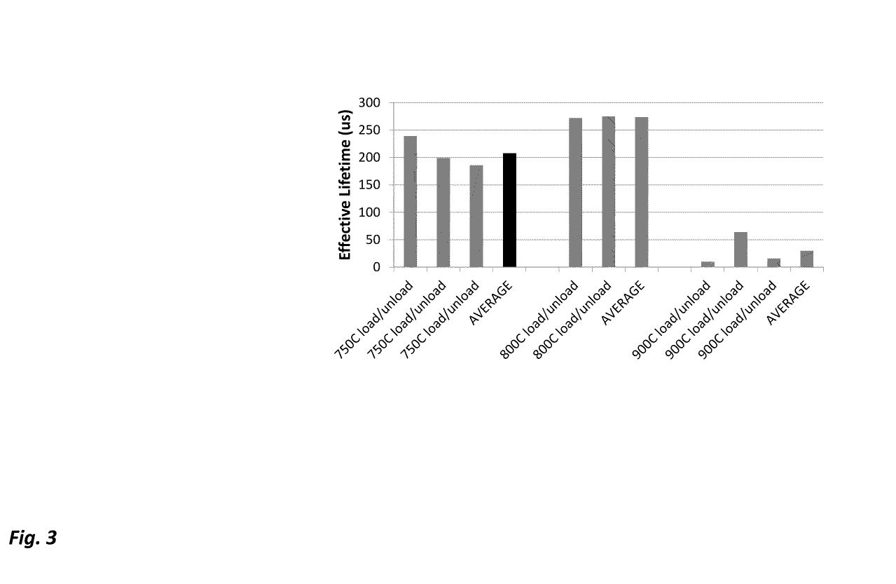

FIG. 3 is a graph of load/unload temperatures vs measured effective lifetime and showing that effective minority carrier lifetime is dependent on the load/unload temperature of the furnace (also known as the idle furnace temperature) with all other parameters being equal. An optimum load/unload temperature (or optimum idle furnace temperature) which maximizes the minority carrier lifetime (or minimizes degradation of the crystalline minority carrier lifetime due to thermal processing). This is because the temperature of load/unload (or idle furnace temperature) and the speed of the push and pull of the batch wafer quartz boat into and out of the furnace directly influences the amount of lifetime-degrading defects formed by oxygen precipitation. The optimum idle furnace temperature in this instance is found to be on the order of 800° C. for this particular anneal process (as compared to 750° and 900° C.) in order to achieve the highest minority carrier lifetime

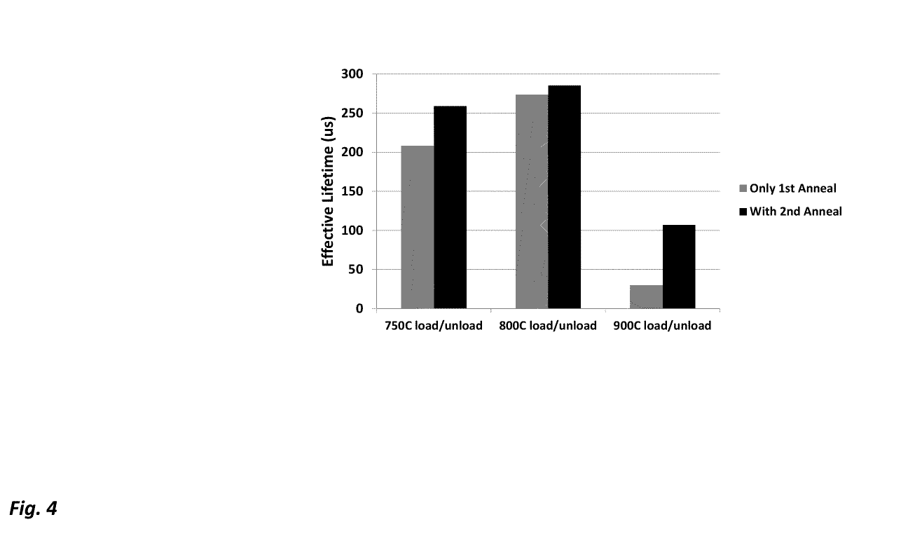

Subsequent to minority carrier lifetime measurements, the wafers were thermally annealed in a batch tube furnace for the second time to determine the capacity for further improvement in minority carrier lifetime. The efficacy of the first furnace anneal was deemed more effective if the second anneal did not result in substantial improvement in the minority carrier lifetime. FIG. 4 is a graph showing the results of the second batch furnace thermal anneal.

The graph of FIG. 4 plots the average minority carrier lifetime before the second batch furnace thermal anneal and compares the average minority carrier lifetime after the second thermal anneal. From FIG. 4 it may be observed at the 800° C. load/unload (or idle furnace temperature) condition, the minority carrier lifetime was sufficiently high to begin with and did not improve much after the 2nd batch furnace thermal anneal. However, a higher-than-optimum 900° C. load/unload (or idle furnace temperature) for the first batch furnace thermal anneal resulted in poor minority carrier lifetime after the first anneal and showed the largest lifetime improvement after the second batch furnace thermal anneal. However, even after the second thermal anneal, the minority carrier lifetime was not as good as the 800° C. load/unload (or idle furnace temperature) condition used with the first thermal anneal. Moreover, a 750° C. load/unload or idle furnace temperature condition yielded minority carrier lifetime results better than the 900° C. load/unload or idle furnace temperature condition, but were still somewhat inferior to the 800° C. load/unload or idle furnace temperature condition, even after the second batch furnace thermal anneal process. A conclusion of this experiment may be formed that with an optimum load/unload or idle furnace temperature of about 800° C. for these specific experimental conditions and parameters, the as-annealed minority carrier lifetime is better than even double-annealed wafers with idle furnace temperature at a different temperature. This not only enables higher solar cell efficiency but also saves the process step of a longer second anneal, hence resulting in lower cell processing cost and also higher thermal processing throughputs. The higher batch furnace processing throughputs of the methods disclosed herein are achieved because of the higher idle furnace temperature (e.g., about 800° C.) as compared to the known methods, and the smaller difference between the idle furnace temperature (e.g., 800° C.) and the actual process temperature (e.g., a process temperature in the range of about 900° C. to 1150° C., typically in the range of about 950° C. to 1100° C.), resulting in faster heat up and cool down ramp times between the idle furnace temperature and the furnace process temperature.

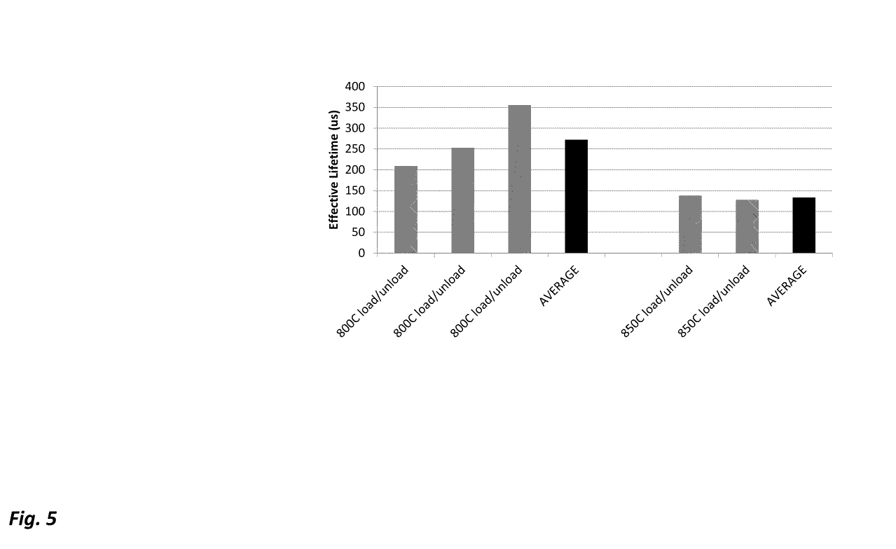

In an additional set of experiments to further confirm the importance of load/unload temperature (or idle furnace temperature) during high temperature batch furnace thermal processing steps for CZ wafers, the boron doped glass (BSG) APCVD process was replaced by an undoped glass (USG) APCVD. FIG. 5 shows the effective lifetime results for these no-emitter test structures. Both 800° C. and 850° C. load/unload furnace temperatures (or idle furnace temperatures) were tested and compared. Because the glass (silicon oxide) is not doped in this case, the anneal does not result in an emitter formation. Thus, the final structure is an n-type wafer with oxide passivation on both sides. Once again the effective minority carrier lifetime was optimal with the 800° C. load/unload (or idle furnace temperature) condition in this particular instance as shown in FIG. 5. A slightly different type of annealing process with the cell structure has resulted in in an optimum temperature of 850C.

In operation, these results detail the importance of loading and unloading temperature or idle furnace temperature in a high temperature solar cell process performed in a batch furnace equipment (e.g. a tube furnace) on CZ wafers during solar cell fabrication. An optimal load/unload temperature (or idle furnace temperature) may be found which maximizes the minority carrier lifetime and the resulting solar cell efficiency. In addition, a relatively fast load/unload of the batch quartz boat with wafers into and out of the batch furnace tube results in the best minority carrier lifetimes at any load/unload temperature (or idle furnace temperature) due to minimization of the oxygen precipitation in CZ wafers. The load/unload of the batch quartz boat with wafers into and out of the batch furnace tube is faster as compared to previously used furnace conditions (for instance with load and unload speeds of at least 50% to 100% faster compared to previously used furnace load/unload speeds). For instance, the load (boat push) time of the batch quartz boat into the furnace (with the furnace tube at the optimal idle temperature range as disclosed herein) may be in the range of a minute up to about 20 minutes. Moreover, the unload (boat pull) time of the batch quartz boat out of the furnace (with the furnace tube at the optimal idle temperature range of this invention) may again be in the range of about a minute up to about 20 minutes. The furnace ramp rate may be in the range of a few degrees to tens of degrees per minute and may minimize the ramp time and cool down time from idle temp. to processing temp. to less than twenty minutes and as short as one minute.

Importantly, preventing extended heat-up and cool-down of the wafer decreases the risk of oxygen precipitation. In other words, extended heat-up and cool-down may increase the risk of oxygen super-saturation and oxygen precipitate formation. Oxygen precipitation within a silicon wafer can be enhanced within a certain temperature range and certain temperature ramp rates. For example, a slow cool down rate of 1 to 5 degrees Celsius per minute from 750C to 550C has been shown to enhance oxygen precipitation. And a fast heat up or cool down can reduce oxygen precipitation.

Further, an in-line furnace where silicon wafers travel on a belt and pass through heated zones and cooling zones may all for faster heat up and cool down rates as compared to a tube furnace. For example, rates from 10 to 150 degrees Celsius per minute, for both heat up and cool down, are possible with an in-line furnace. And while a tube furnace typically is limited to 1 to 20 degrees Celsius per minute, an in-line furnace with fast heat up and cool down rates may be used to further minimize oxygen precipitation in silicon wafers.

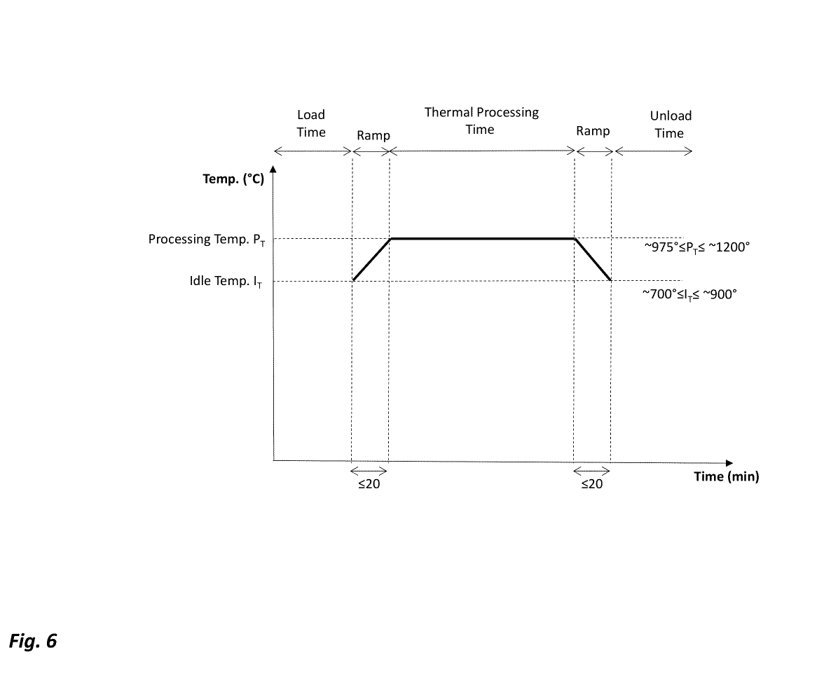

FIG. 6 is a graphic timeline depiction of the load, high-temperature processing, and unload process flow. The load and unload of the wafer into the furnace, as the wafer moves from room temp. to idle furnace temp. is minimized and is in the range of less than ten minutes and more specifically approximately five minutes. The ramp time from idle temperature to processing temperature may be adjusted to be minimal, dependent on other factors, in order to minimize the wafers exposure to certain temperature ranges during the heat-up and cool-down period.

In operation, the disclosed solutions provide high-throughput thermal processing methods which suppress or reduce degradation of minority carrier lifetimes of starting silicon substrates. These methods may be particularly applicable to suppression of silicon oxide precipitates and preventing degradation of bulk minority carrier lifetime during thermal processing of a silicon substrate for solar cell fabrication.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for thermal processing of a silicon substrate, the method comprising:
heating a silicon substrate in a furnace to an idle load temperature in the range of approximately 700° to 900° C.;
heating said silicon substrate in said furnace to a temperature in the range of approximately 975° to 1200° C. in less than approximately 20 minutes; and
cooling the temperature of said silicon substrate to an idle unload temperature in the range of approximately 700° to 900° C. in less than approximately 20 minutes.

2. The method of claim 1, wherein said idle load and unload temperatures are in the range of approximately 800° to 850° C.

3. The method of claim 1, wherein said processing of said silicon substrate in said furnace is at a temperature in the range of approximately 975° to 1200° C.

4. The method of claim 1, wherein said silicon substrate is a crystalline silicon substrate.

5. The method of claim 1, wherein said silicon substrate is a monocrystalline silicon substrate.

6. The method of claim 1, wherein said silicon substrate is a multi-crystalline silicon substrate.

7. The method of claim 1, wherein said processing of said silicon substrate in said furnace is a thermal anneal process.

8. The method of claim 1, further comprising depositing at least one dopant-containing material on a least a portion of the surface of said silicon substrate before said heating of said silicon substrate in a furnace to said idle load temperature.

9. The method of claim 8, wherein said processing of said silicon substrate in said furnace is a thermal process for dopant drive-in.

10. The method of claim 8, wherein said processing of said silicon substrate in said furnace is a thermal process for surface passivation.

11. The method of claim 1, wherein said heating of said silicon substrate and said cooling the temperature of said silicon substrate is performed in the presence of an ambient gas.

12. The method of claim 11, wherein said ambient gas is nitrogen.

13. The method of claim 11, wherein said ambient gas comprises a combination of an inert gas and an oxidizing ambient.

14. The method of claim 1, wherein said silicon substrate is a CZ wafer.

15. The method of claim 1, further comprising a second processing of said silicon substrate at a temperature greater than 1200° C. before said cooling the temperature of said silicon substrate to an idle unload temperature.

16. The method of claim 1, wherein said furnace is a batch tube furnace.

17. The method of claim 1, wherein said furnace is an in-line furnace.

18. A method for thermal processing of a silicon substrate, the method comprising:
depositing dopant on a least a portion of the surface of a CZ monocrystalline silicon substrate;
heating said CZ monocrystalline silicon substrate in a furnace to an idle load temperature in the range of approximately 800° to 850° C.;
heating said CZ monocrystalline silicon substrate in said furnace at a temperature in the range of approximately 1000° to 1100° C. to drive in dopants and passivate the surface of said CZ monocrystalline silicon substrate in less than approximately 20 minutes; and
cooling the temperature of said CZ monocrystalline silicon substrate to an idle unload temperature in the range of approximately 800° to 850° C. in less than approximately 20 minutes.

19. The method of claim 18, wherein said heating of said CZ monocrystalline silicon substrate and said cooling the temperature of said CZ monocrystalline silicon substrate is performed in the presence of an ambient gas.

20. The method of claim 19, wherein said ambient gas is nitrogen.

21. The method of claim 19, wherein said ambient gas comprises a combination of an inert gas and an oxidizing ambient.

22. A method for suppression of silicon oxide precipitates and preventing degradation of bulk minority carrier lifetime during thermal processing of a silicon substrate for solar cell fabrication, the method comprising:
loading said silicon substrate into a batch tube furnace with an idle load temperature in the range of approximately 700 degrees to 900 degrees C.;
heating said silicon substrate in said furnace to a temperature in the range of approximately 975 degrees to 1200 degrees C. in less than approximately 20 minutes and annealing said silicon substrate at such temperature for at least several minutes;
cooling the temperature is said silicon substrate to an idle unload temperature in the range of approximately 700 degrees to 900 degrees C. in less than approximately 20 minutes; and
unloading said silicon wafer from said batch tube furnace.
